(19) United States
(12) Patent Application Publication
(10) Pub. No.: US 2024/0421326 A1
(43) Pub. Date: Dec. 19, 2024

(54) COATING SYSTEM, ELECTRODE PLATE WITH A COATING SYSTEM OF THIS TYPE, METHOD FOR THE PRODUCTION THEREOF, AND FUEL CELL, ELECTROLYZER OR REDOX FLOW CELL

(71) Applicant: Schaeffler Technologies AG & Co. KG, Herzogenaurach (DE)

(72) Inventors: Dr. Jan Martin Stumpf, Erlangen (DE); Romina Baechstaedt, Wooster, OH (US); Moritz Wegener, Erlangen (DE); Ladislaus Dobrenizki, Hochstaat (DE); Joachim Weber, Erlangen (DE); Jeevanthi Vivekananthan, Krefeld (DE)

(73) Assignee: Schaeffler Technologies AG & Co. KG, Herzogenaurach (DE)

(21) Appl. No.: 18/706,465

(22) PCT Filed: Jun. 30, 2022
(86) PCT No.: PCT/DE2022/100476

§ 371 Date: May 1, 2024

(30) Foreign Application Priority Data
Nov. 2, 2021 (DE) 102021128468.6

(51) Int. Cl. H01M 8/0228; C23C 14/02; C23C 14/06; C23C 14/08; C23C 14/16; C23C 14/34; H01M 8/0208; H01M 8/021; H01M 8/0215; H01M 8/0217; H01M 8/10; H01M 8/1004

(52) U.S. Cl. CPC H01M 8/0228; C23C 14/025; C23C 14/0641; C23C 14/0664; C23C 14/086; C23C 14/16; C23C 14/3464; H01M 8/0208; H01M 8/021; H01M 8/0215; H01M 8/0217; H01M 8/1004; H01M 2008/1095

(57) ABSTRACT

A coating system for coating a metal substrate to form an electrode plate, comprising at least one top coat made of metal oxide, at least one intermediate coat carrying the top coat, and a base coat carrying the intermediate coat(s). The top coat is formed by a network of nanofibres either a) formed by indium tin oxide, which has optionally a third doping with at least one element from the group comprising carbon, nitrogen, boron, fluorine, hydrogen, phosphorus, sulphur, chlorine, bromine, aluminium, silicon, titanium, chromium, cobalt, nickel, copper, zircon, niobium, molybdenum, silver, antimony, hafnium, tantalum, tungsten or b) formed by doped tin oxide, wherein the tin oxide has at least one of the elements from the group comprising niobium, tantalum, antimony, fluorine as a fourth doping.

### CROSS-REFERENCE TO RELATED APPLICATIONS

This application is the U.S. National Phase of PCT Appln. No. PCT/DE2022/100476, filed Jun. 30, 2022, which claims the benefit of German Patent Appln. No. 102021128468.6, filed Nov. 2, 2021, the entire disclosures of which are incorporated by reference herein.

### TECHNICAL FIELD

The disclosure relates to a coating system for coating a metal substrate to form an electrode plate, comprising at least one top coat made of metal oxide. The disclosure further relates to an electrode plate comprising a metal substrate and to such a coating system and to a method for the production thereof. Furthermore, the disclosure relates to a fuel cell, an electrolyzer or a redox flow cell comprising at least one such electrode plate.

### BACKGROUND

A bipolar plate for a fuel cell or an electrolyzer is already known from DE 100 58 337 A1, in which a conductive and corrosion-resistant protective coating made of a metal oxide is formed on at least one side of a metal sheet. The metal oxide is formed in particular from an oxide of the elements or alloys from the group comprising tin, zinc and indium. A dopant which ensures conductivity and consists of at least one element from the group comprising aluminum, chromium, silver, boron, fluorine, antimony, chlorine, bromine, phosphorus, molybdenum and carbon can be present in the metal oxide. The metal sheets used are those made of aluminum, copper, stainless steel, chrome-plated stainless steel, titanium, titanium alloys and iron-containing compounds, which can have a coating of at least one of the elements tin, zinc, nickel and chromium.

### SUMMARY

It is an object of the disclosure to provide an improved coating system for an electrode plate and to provide such an electrode plate. Furthermore, it is an object of the disclosure to provide a method for the production of the electrode plate and to propose a fuel cell, an electrolyzer or a redox flow cell with at least one such electrode plate.

The object is solved by the coating system for coating a metal substrate to form an electrode plate, comprising at least one top coat made of metal oxide, at least one intermediate coat carrying the top coat and a base coat carrying the intermediate coat(s),
wherein the base coat is formed from titanium or a titanium-niobium alloy or chromium,
wherein the at least one intermediate coat is formed from titanium niobium nitride and/or titanium niobium carbide and/or titanium niobium carbonitride and/or titanium carbide and/or titanium nitride and/or chromium carbide and/or chromium carbonitride and/or homogeneous indium tin oxide, optionally doped with a first dopant, and/or homogeneous tin oxide doped with a second dopant, and
wherein the top coat is formed from a network of nanofibers either
a) of indium tin oxide, which optionally comprises a third dopant with at least one element from the group comprising carbon, nitrogen, boron, fluorine, hydrogen, phosphorus, sulfur, chlorine, bromine, aluminum, silicon, titanium, chromium, cobalt, nickel, copper, zirconium, niobium, molybdenum, silver, antimony, hafnium, tantalum and tungsten, or
b) of doped tin oxide, wherein the tin oxide has as a fourth dopant at least one of the elements from the group comprising niobium, tantalum, antimony and fluorine.

The coating system is characterized by high long-term stability with simultaneously high electrical conductivity and low costs, since it dispenses with noble metal. In addition, the coating system ensures excellent corrosion protection for a metallic base material or substrate of an electrode plate, in particular a bipolar plate. Indium tin oxide is also referred to below by the abbreviation ITO.

The coating system is preferably formed using a PVD or a CVD process (PVD: physical vapor deposition; CVD: chemical vapor deposition) or a PACVD process (PACVD: plasma-assisted chemical vapor deposition).

Nanofibers are elongate or stem-like structures that have a diameter of up to 200 nm and a length of up to 1000 nm. The nanofibers can be tapered.

For the formation of a top coat from a network of nanofibers, reference is made here to the publication “3D ITO-nanowire networks as transparent electrode for all terrain substrate”, Qiang Li et al., Scientific Reports (2019) 9:4983. See below: https://doi.org/10.1038/s41598-019-41579-2

The applicant was also able to produce ITO nanofibers for fuel cell, electrolysis and redox flow bipolar plates using non-reactive sputtering technology with a deposition rate of 40 Å/min and from a target made of In₂O₃:SnO₂ with a concentration of 90:10 at %. The temperature and the SnO₂ content are the main growth factors in the production of the ITO nanofibers. Growth occurs through atoms that are vaporized from the target and deposited on a substrate. The temperature range for growth is 150° C. to 500° C. Increasing the temperature increases the mean fiber length and the mean diameter of the fibers, reduces the neighbor distance and increases the number of fibers per unit area. The SnO₂ content is preferably a maximum of 30 at %. Development of the mean length and the mean diameter of the nanofibers depends on deposition time. The ITO nanofibers preferably grow on a thin, dense ITO layer.

Such nanofiber production is also possible on the basis of doped tin oxide.

The first dopant preferably corresponds to the third dopant and the second dopant preferably corresponds to the fourth dopant.

A concentration of the elements of the first and/or third dopant in the indium tin oxide is in particular in the range of >0 to 20 at %, preferably in the range of 0.5 to 20 at %.

A concentration of the elements of the second and/or the fourth dopant in the tin oxide is in particular in the range of >0 to 20 at %, preferably in the range of 0.5 to 20 at %.

Top coats made of indium tin oxide which have an indium content in the range of 70 to 90 at % are particularly preferred here. Indium contents in the range of 75 to 85 at % are particularly preferred which have a high level of electrical conductivity.

The base coat is used in particular as an adhesion promoter between a metal substrate and the at least one intermediate coat. Furthermore, the base coat forms conductive oxides and thus provides galvanic corrosion protection for the metal substrate of a bipolar plate. The base coat preferably has a coat thickness in the range of 1 nm to 300 nm.

In particular, the intermediate coat is also used as an adhesion promoter between the base coat and the top coat. Furthermore, depending on the selection, the at least one intermediate coat can form conductive oxides and thus provide galvanic corrosion protection for the base coat and the metal substrate of an electrode plate. The at least one intermediate coat also provides a barrier for hydrogen, preventing it from penetrating toward the metal substrate and damaging it. A coat thickness of an individual intermediate coat is preferably selected in the range of 0.1 to 3.0 μm. However, there can be two or more intermediate coats.

The top coat protects the base coat and the intermediate coat(s) mechanically and from corrosive attack. The top coat in particular has a coat thickness in the range of 0.01 to 15 μm, in particular in the range of 0.1 to 3 μm.

The coating system according to the disclosure, comprising the base coat, at least one intermediate coat and the top coat, preferably has a total thickness in the range of 0.1 to 20 μm.

In particular, the following coating systems for coating a metal substrate, preferably made of steel, in particular austenitic steel or austenitic stainless steel, have proven to be advantageous for forming an electrode plate:

### EXAMPLE 1

Base coat: TiNb Coat thickness: 100 nm
Intermediate coat: TiNbN Coat thickness: 300 nm
Top coat: Indium tin oxide nanofibers with 80 vol % indium content Coat thickness: 100 nm

### EXAMPLE 2

Base coat: TiNb Coat thickness: 100 nm
1. Intermediate coat: TiNbN Coat thickness: 200 nm
2. Intermediate coat: homogeneous indium tin oxide Coat thickness: 200 nm

Top coat: Indium tin oxide nanofibers with 90 vol % indium content Coat thickness: 100 nm

### EXAMPLE 3

Base coat: TiNb Coat thickness: 100 nm
1. Intermediate coat: TiNbCN Coat thickness: 200 nm
2. Intermediate coat: TiNbN Coat thickness: 200 nm
Top coat: doped tin oxide nanofibers Coat thickness: 100 nm

The object is achieved for an electrode plate comprising a metal substrate and a coating system according to the disclosure with an electrode plate structure in the following order:
metal substrate,
base coat,
intermediate coat(s) and
top coat.

The electrode plate preferably comprises a metal substrate or a metal carrier plate, preferably made of steel, in particular made of austenitic steel or stainless steel. Alternatively, the substrate may be formed of titanium or a titanium alloy or aluminum or an aluminum alloy or zinc or a zinc alloy or a tin alloy or copper or a copper alloy or nickel or a nickel alloy or silver or a silver alloy or chromium or a chromium alloy.

A carrier plate can be designed to be single-or multi-part. In particular, the electrode plate is designed as a bipolar plate.

According to the disclosure, the method for producing an electrode plate according to the disclosure comprises the following steps:
providing the metal substrate;
forming the base coat on a surface of the metal substrate;
forming the at least one intermediate coat on the base coat; and
forming the top coat on the side of the at least one intermediate coat facing away from the base coat,
wherein the coating system is formed on the metal substrate by non-reactive sputtering.
This is a deposition process that can be carried out cost-effectively on a series scale and can also be used to produce nanofibers.

The object is further achieved for a fuel cell, in particular an oxygen-hydrogen fuel cell, or an electrolyzer, in particular for producing hydrogen and oxygen from water, or a redox flow cell, in particular comprising at least one organic electrolyte, comprising at least one electrode plate according to the disclosure. The fuel cell preferably comprises at least one polymer electrolyte membrane.

In the test, the coating system exhibited stability up to at least 1.4 V in relation to Ag/AgCl ex situ under harsh fuel cell conditions in a 0.5-mM H₂SO₄ electrolyte at pH 3+0.1 ppm HF, and is therefore comparable to the noble metal coating. The contact resistance before and after this electrochemical loading (see parameters above) is <3 mOhm·cm² at a contact pressure of 100 N/cm² and a measuring temperature of 24° C.

The corrosion currents are <10⁻⁷ A/cm² under the relevant fuel cell application potentials up to 1.0 V in relation to Ag/AgCl.

No attack on the coating or substrate was detected optically or microscopically up to at least 1.4 V in relation to Ag/AgCl. A stainless steel substrate with the material number 1.4404 according to DIN was used as the substrate.

In the test, the coating system exhibited stability up to at least 2.2 V in relation to the NHE (normal hydrogen electrode) ex situ under harsh electrolysis conditions in an H₂SO₄ electrolyte at pH 4. The contact resistance before and after this electrochemical loading (see parameters above) is <3 mOhm·cm² at a contact pressure of 100 N/cm² and a measuring temperature of 24° C.

No attack on the coating or substrate was detected optically or microscopically up to at least 2.2 V in relation to the NHE. A stainless steel substrate with the material number 1.4404 according to DIN was used as the substrate.

### BRIEF DESCRIPTION OF THE DRAWINGS

FIGS. 1 to 4 are intended to explain, by way of example, a coating system according to the disclosure, an electrode plate formed therewith in the form of a bipolar plate and a fuel cell. In the drawings:

FIG. 1 shows a bipolar plate comprising the coating system;

FIG. 2 is a schematic representation of a fuel cell system comprising a plurality of fuel cells;

FIG. 3 shows an enlarged view of a cross section through a coating system shown by way of example; and

FIG. 4 shows a scanning electron micrograph of a top coat.

### DETAILED DESCRIPTION

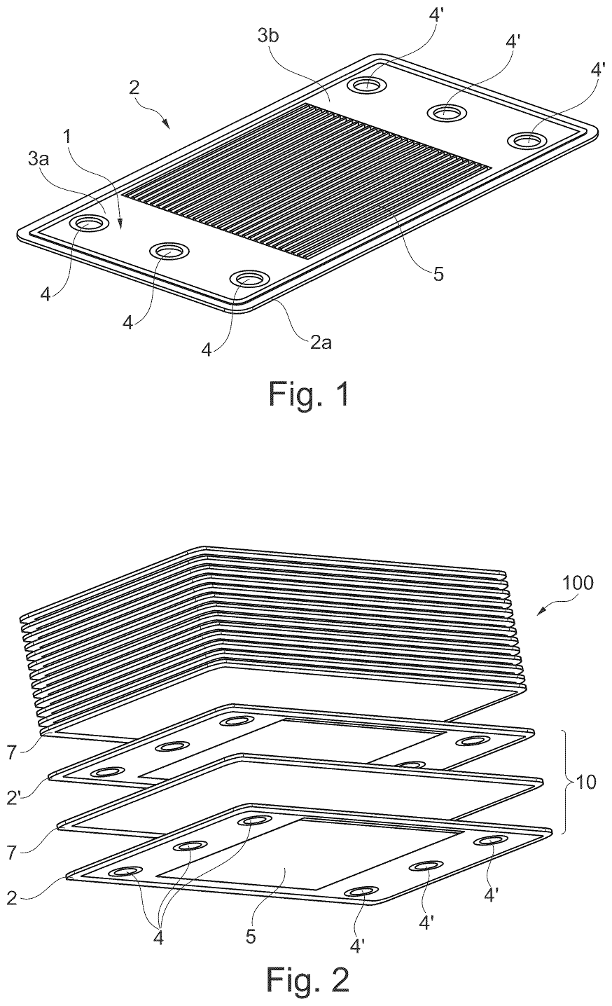

FIG. 1 shows an electrode plate 2 in the form of a bipolar plate having a coating system 1, the plate here having a metal substrate 2a or a metal carrier plate made of austenitic stainless steel. The bipolar plate has an inflow region 3a with openings 4 and an outlet region 3b with further openings 4′, which are used to supply a fuel cell with process gases and to remove reaction products from the fuel cell. The bipolar plate also has a gas distribution structure 5 on each side, which is provided for contact with a polymer electrolyte membrane 7 (cf. FIG. 2).

FIG. 2 is a schematic representation of a fuel cell system 100 comprising a plurality of fuel cells 10. Each fuel cell 10 comprises a polymer electrolyte membrane 7 with neighboring electrode plates 2, 2′ in the form of bipolar plates on both sides. The same reference signs as in FIG. 1 indicate identical elements.

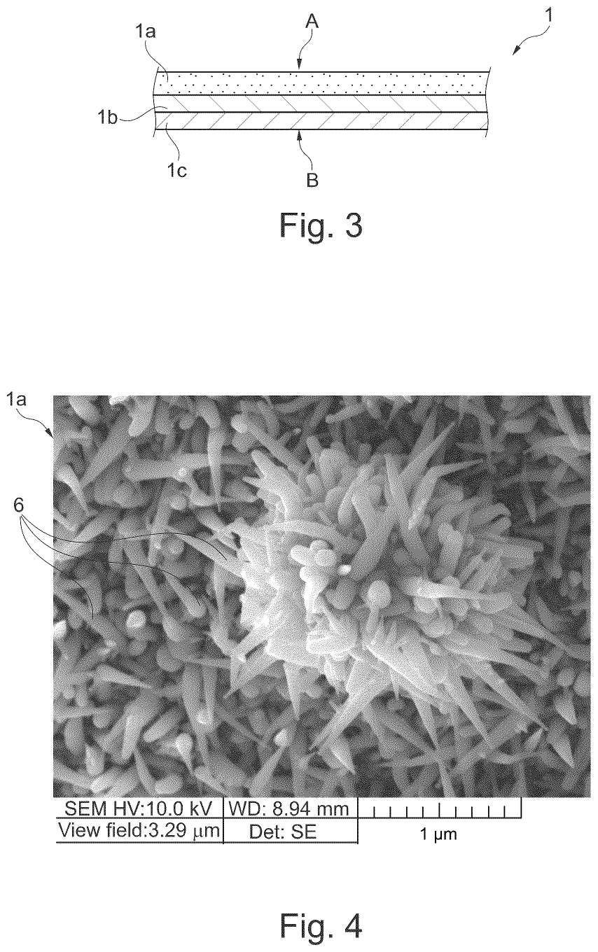

FIG. 3 shows a cross section through the coating system 1 according to FIG. 1. It can be seen that there are a top coat 1a, an intermediate coat 1b and a base coat 1c. The base coat 1c is disposed on a side B of the coating system 1 which is arranged facing the substrate 2a of the bipolar plate 2. The top coat 1a is disposed on a side A of the coating system 1 which is arranged facing away from the substrate 2a of an electrode plate 2. Alternatively, the coating system 1 can also have a plurality of intermediate coats 1b.

FIG. 4 shows a scanning electron micrograph of the surface of a top coat 1a made of a network of nanofibers 6, here made of indium tin oxide.

### LIST OF REFERENCE SIGNS

1 Coating system
1a Top coat
1b Intermediate coat(s)
1c Base coat
2, 2′ Electrode plate
2a Metal substrate
3a Inflow region
3b Outlet region
4, 4°

Opening
5 Gas distribution structure
6 Nanofibers
7 Polymer electrolyte membrane
10 Fuel cell
100 Fuel cell system
A Side of the coating system 1 facing away from the substrate 2a
B Side of the coating system 1 facing the substrate 2a

1. A coating system for coating a metal substrate to form an electrode plate, comprising:
at least one top coat made of metal oxide,
at least one intermediate coat carrying the top coat, and
a base coat carrying the intermediate coat(s),
wherein the base coat is formed from at least one of titanium or a titanium-niobium alloy or chromium, wherein the at least one intermediate coat is formed from at least one of titanium niobium nitride, titanium niobium carbide, titanium niobium carbonitride, titanium carbide, titanium nitride, chromium carbide, chromium carbonitride, homogeneous indium tin oxide, doped with a first dopant, or homogeneous tin oxide doped with a second dopant, and
wherein the top coat is formed from a network of nanofibers either a) of indium tin oxide, which comprises a third dopant with at least one element from the group comprising carbon, nitrogen, boron, fluorine, hydrogen, phosphorus, sulfur, chlorine, bromine, aluminum, silicon, titanium, chromium, cobalt, nickel, copper, zirconium, niobium, molybdenum, silver, antimony, hafnium, tantalum and tungsten, or b) of doped tin oxide, wherein the tin oxide has as a fourth dopant at least one of the elements from the group comprising niobium, tantalum, antimony and fluorine.

2. The coating system according to claim 1, wherein the first dopant corresponds to the third dopant and wherein the second dopant corresponds to the fourth dopant.

3. The coating system according to claim 1, wherein a concentration of the elements of at least one of the first or the third dopant in the indium tin oxide is in the range of >0 to 20 at %.

4. The coating system according to claim 1, wherein a concentration of the elements of at least one of the second or the fourth dopant in the tin oxide is in the range of >0 to 20 at %.

5. The coating system according to claim 1, wherein the top coat made of indium tin oxide has an indium content in the range of 70 to 90 at %.

6. The coating system according claim 1, wherein the base coat has a coat thickness in the range of 1 to 300 nm.

7. The coating system according claim 1, wherein the at least one intermediate coat has a coat thickness in the range of 0.1 μm to 3.0 μm.

8. The coating system according to claim 1, wherein the top coat has a coat thickness in the range of 0.01 μm to 15 μm.

9. An electrode plate, comprising: a metal substrate and a coating system comprising at least one top coat made of metal oxide,
at least one intermediate coat carrying the top coat, and
a base coat carrying the intermediate coat(s),
wherein the base coat is formed from at least one of titanium or a titanium-niobium alloy or chromium, wherein the at least one intermediate coat is formed from at least one of titanium niobium nitride, titanium niobium carbide, titanium niobium carbonitride, titanium carbide, titanium nitride, chromium carbide, chromium carbonitride, homogeneous indium tin oxide, doped with a first dopant, or homogeneous tin oxide doped with a second dopant, and wherein the top coat is formed from a network of nanofibers either a) of indium tin oxide, which comprises a third dopant with at least one element from the group comprising carbon, nitrogen, boron, fluorine, hydrogen, phosphorus, sulfur, chlorine, bromine, aluminum, silicon, titanium, chromium, cobalt, nickel, copper, zirconium, niobium, molybdenum, silver, antimony, hafnium, tantalum and tungsten, or b) of doped tin oxide, wherein the tin oxide has as a fourth dopant at least one of the elements from the group comprising niobium, tantalum, antimony and fluorine;
the electrode plate having an electrode plate structure in the following order: metal substrate,
base coat,
intermediate coat(s) and
top coat.

10. The electrode plate according to claim 9, wherein the metal substrate is formed from steel.

11. The electrode plate according to claim 9, wherein the electrode plate is part of a fuel cell.

12. The electrode plate of claim 11, wherein the fuel cell includes at least one polymer electrolyte membrane.

13. A method for producing an electrode plate comprising the following steps: providing a metal substrate; forming a base coat on a surface of the metal substrate; forming the at least one intermediate coat on the base coat; and forming the a top coat on a side of the at least one intermediate coat facing away from the base coat, wherein the coating system is formed on the metal substrate by non-reactive sputtering; and
wherein the base coat is formed from at least one of titanium or a titanium-niobium alloy or chromium, wherein the at least one intermediate coat is formed from at least one of titanium niobium nitride, titanium niobium carbide, titanium niobium carbonitride, titanium carbide, titanium nitride, chromium carbide, chromium carbonitride, homogeneous indium tin oxide, doped with a first dopant, or homogeneous tin oxide doped with a second dopant, and wherein the top coat is formed from a network of nanofibers either a) of indium tin oxide, which comprises a third dopant with at least one element from the group comprising carbon, nitrogen, boron, fluorine, hydrogen, phosphorus, sulfur, chlorine, bromine, aluminum, silicon, titanium, chromium, cobalt, nickel, copper, zirconium, niobium, molybdenum, silver, antimony, hafnium, tantalum and tungsten, or b) of doped tin oxide, wherein the tin oxide has as a fourth dopant at least one of the elements from the group comprising niobium, tantalum, antimony and fluorine;
the electrode plate having an electrode plate structure in the following order: metal substrate,
base coat,
intermediate coat(s) and
top coat.

14. The electrode plate according to claim 9, wherein the first dopant corresponds to the third dopant and wherein the second dopant corresponds to the fourth dopant.

15. The electrode plate according to claim 9, wherein a concentration of the elements of at least one of the first or the third dopant in the indium tin oxide is in the range of >0 to 20 at %.

16. The electrode plate according to claim 9, wherein a concentration of the elements of at least one of the second or the fourth dopant in the tin oxide is in the range of >0 to 20 at %.

17. The electrode plate according to claim 9, wherein the top coat made of indium tin oxide has an indium content in the range of 70 to 90 at %.

18. The electrode plate according to claim 9, wherein the base coat has a coat thickness in the range of 1 to 300 nm.

19. The electrode plate according to claim 9, wherein the at least one intermediate coat has a coat thickness in the range of 0.1 μm to 3.0 μm.

20. The electrode plate according to claim 9, wherein the top coat has a coat thickness in the range of 0.01 μm to 15 μm.
